(19) United States
(12) Patent Application Publication
(10) Pub. No.: US 2026/0147046 A1
(43) Pub. Date: May 28, 2026

(54) DC DISTRIBUTOR FOR A BATTERY TEST BENCH

(71) Applicant: ZF Friedrichshafen AG, Friedrichshafen (DE)

(72) Inventors: Sebastian GOTTSCHALLER, Tiefenbach (DE); Dirk STÜBENER, München (DE)

(73) Assignee: ZF Friedrichshafen AG, Friedrichshafen (DE)

(21) Appl. No.: 19/397,223

(22) Filed: Nov. 21, 2025

(30) Foreign Application Priority Data
Nov. 22, 2024 (DE) 10 2024 211 239.9
Mar. 20, 2025 (DE) 10 2025 110 881.1

(51) Int. Cl. G01R 31/36; G01R 1/20; G01R 1/36; G01R 31/34

(52) U.S. Cl. CPC G01R 31/3644; G01R 1/206; G01R 1/36; G01R 31/34

(57) ABSTRACT

A test bench (2) for the electrical testing of test objects (4) with the help of an electric high-power direct voltage (UG) contains at least one energy source (12) with a generator (14) for alternating voltage (UW) and an inverter (16) with first two-pole DC-voltage interfaces (18). Test stations (20) for the test objects (4) have a resonance converter (22) with a second two-pole DC-voltage interface (26) and a step-down converter (24) with a two-pole DC-voltage connection terminal (28) for the test object (4). A modular DC-voltage bus (30) has a series circuit of uniform distributors (34) with bus bars (32) that can be connected in series, and branches (36) which lead from the bus bar (32) to third two-pole DC-voltage interfaces (38), with isolator switches (40). Each of the first (18) and second (26) DC-voltage interfaces is connected to one of the respective third DC-voltage interfaces (38).

### RELATED APPLICATIONS

This application claims the benefit of and right of priority under 35 U.S.C. § 119 to German Patent Application no. 10 2025 110 881.1, filed on 20 Mar. 2025, and to German Patent Application no. 10 2024 211 239.9, filed on 22 Nov. 2024, the contents of which are incorporated herein by reference in their entireties.

### FIELD OF THE DISCLOSURE

The invention relates to a test bench. A relevant test bench in the present context serves for the electrical testing of test objects, for example electric drive units or drive batteries of electric vehicles, using DC-voltage between two poles with comparatively high powers in the tens of kilowatts range. One of the test objects can be or is connected in each case at several test stations of the test bench. Then, the test objects can draw electrical power from the test station or deliver power thereto.

### BACKGROUND

From WO 20212/174278 A1 it is known that electrically operated test stations as a rule comprise inverter arrangements with a plurality of inverters, whether for testing drivetrains of electric vehicles, hybrid vehicles, conventional vehicles with internal combustion engines, the mechanical components such as the transmission, or the battery storage systems themselves. In fact, battery storage systems are often tested in parallel, in such manner that a number of battery cells, battery modules or battery packs are tested at the same time with inverters arranged in parallel.

### SUMMARY

The purpose of the present invention is to propose improvements relating to a test bench.

This objective is achieved by a test bench as disclosed herein. Preferred or advantageous embodiments of the invention and other invention categories emerge from the present disclosure, including the description given below and the attached figures.

The test bench is one designed for two-pole test objects, i.e., it serves for the testing or connection of two-pole test objects. The two poles constitute a plus-pole and a minus-pole for a DC voltage. The test bench serves for the electrical testing of the test objects. The test objects are tested under DC voltage between the two poles with the help of an electric current to be fed into and/or drawn from the test object concerned. For this the size of the test bench is such that the test object can be exposed to comparatively high electric power. In this context the test bench is designed for comparatively high electric loads. The nominal/maximum value of the possible electric power for each test object is typically 250 kW up to 1 MW, at a nominal voltage typically of around 200 V to around 800 V and a nominal current typically of 1000 A to 2000 A.

The test bench contains at least one energy source. The energy source can feed electric power into the rest of the test bench, or if necessary, draw power therefrom. Thus, the terms “source/production/etc.” should be understood broadly. For example, the “energy source” is in this case designed bi-directionally and can, if necessary, also be operated as an energy sink.

Each energy source contains a generator (if necessary bi-directional). The generator serves to produce an alternating voltage for the rest of the test bench. Each energy source also contains at least one inverter, which is connected to the generator. The inverter serves to convert the alternating voltage at the generator to a direct-current voltage. Accordingly, on the side facing away from the generator (viewed in switch-technology terms) the inverter or the energy source concerned has at least one first two-pole DC-voltage interface.

The test bench also comprises a plurality of test stations. Each test station serves for the testing or connection of one test object in each case. The test stations too are of two-pole design, for the two-pole connection of a test object so that it can be supplied with DC-voltage. Each test station contains a resonance converter. The resonance converter or the test station comprises a second two-pole DC-voltage interface. Each of the test stations contains a step-down converter which is connected to the respective resonance converter. On the side facing away from the resonance converter (in the circuit technology sense; see above) the test station or step-down converter comprises a two-pole DC-voltage connection terminal. This serves as the two-pole connection of the test object concerned.

The resonance converter and the step-down converter serve to convert the DC-voltage at the second two-pole DC-voltage interface, by way of an intermediate alternating voltage, into a lower DC-voltage at the DC-voltage connection terminal (if necessary bidirectional).

The test bench contains a modular DC-voltage bus.

The DC-voltage bus contains a series circuit of at least two uniform distributors. Each uniform distributor contains a bus bar of two-pole design. Relative to their bus bars the uniform distributors can be connected in series. In other words, by connecting in series the two-pole (partial) bus bars of each uniform distributor a common two-pole (conjoint) bus bar extending over all the uniform distributors connected in series is produced.

Each of the uniform distributors contains at least two branches. Each of the branches is of two-pole design and connected to the bus bar in a bipolar manner. Thus, each of the branches leads from the bus bar to a respective third two-pole DC-voltage interface. In other words, each branch opens onto a third DC-voltage interface of its own and of the uniform distributor.

Each branch contains a two-pole isolator switch. Thus, by means of the isolator switch the respective third DC-voltage interface can be electrically separated in a bipolar manner and hence completely from the bus bar, or electrically connectable / connected thereto.

In the test bench each of the first and each of the second DC-voltage interfaces is connected respectively to one of the third DC-voltage interfaces. Thus, all the energy sources and test stations are connected to one another by way of the DC-voltage bus in an electrically conducting and two-pole manner.

Preferably, at least one of the uniform distributors has precisely six branches. In particular, on one of the uniform distributors an energy source is connected to a total of four of its branches. Then, a respective test station can be or is connected to the other two branches.

Basically however, any desired number, and in specific applications in each case, the appropriate number of uniform distributors can be provided.

Thanks to the modular nature of the DC-voltage bus, in the context of project planning the test bench can be simply scaled by adding or removing further uniform distributors to or from the series circuit. Thanks to the isolator switches, individual branches can be activated selectively without activating other branches. For example, the isolator switch can be opened in one of the branches so that there, for example, the test station connected there can be removed or exchanged, or maintenance work can be carried out on it since it is switched to a voltage-free condition. During that, the other test stations, or the rest of the test bench, can continue operating.

In a preferred embodiment, at least one of the isolator switches comprises a safety device to guard against re-connection. Thus, after the isolator switch has been opened, in a manner customary according to the state of the art, it can be ensured that re-connection of the isolator switch is reliably prevented. Work on an energy source or test station connected to the third DC-voltage interface concerned can therefore be carried out safely. The safety device is for example a fastening means for a padlock that, when present or affixed, prevents the re-connection of the isolator switch.

In a preferred embodiment, at least one of the branches contains at least one and in particular two bridge terminals. In other words, at least one branch comprises at least one bridge terminal. Each of the bridge terminals is active in relation to one of the two poles. The bridge terminal separates the pole conductor concerned, i.e., the electrical connection of a pole of the bus bar to a pole of the third DC-voltage interface. In the bridge terminal a short-circuit element (then an element of the test bench) can optionally be used in order to bridge across it. The electric connection of the pole via the bridge terminal is then re-established. Alternatively, a safety element (then an element of the test bench) can be used in the bridge terminal in order to bridge across it. An electric safety element, for example an electric fuse, then protects the corresponding pole and with it the third DC-voltage interface or the branch as a whole electrically, for example against too large a current.

Thus, a short-circuit element or a safety element bridges across the bridge terminal in each case and re-establishes the electrical connection between the third interface and the bus bar in relation to that pole (if necessary, electrically protected or by short-circuit). The branches can therefore be used universally, in particular for the connection of an energy source (use of a short-circuit element) or of a test station (use of an electric safety element). In other words, in that way the branches can be configured.

In a preferred embodiment, the test bench comprises in particular precisely one pre-charging device. The pre-charging device can be connected optionally or if necessary, specifically to precisely one of the test stations. The pre-charging device is designed, in the test station to which it is connected at the time, to feed in an electric pre-charge. This takes place in particular before the test station is connected to the rest of the test bench. Connection takes place by forming the electrical connection to the bus bars, i.e. by closing the isolator switch. Accordingly, for example, the pre-charging device can be connected and activated when the test station concerned, with its second interface, is already connected to the third interface but the isolator switch is still open. Thus, by an appropriate pre-charging of any capacities in the test station, the isolator switch can be closed, and the test station can be connected to the bus bar securely, without any sudden current flow taking place via the branch, for example due to capacities at the test station that have to be charged or discharged.

In a preferred embodiment at least one of the energy sources comprises a plurality of, in particular four, two-pole DC-voltage interfaces. In other words, the energy source or its inverter(s) is/are connected via several parallel two-pole interfaces to the direct-current bus or the bus bar, so that the respective current loading of the interfaces is reduced. In that way, for example, an energy source with a nominal power of 1 MW can be divided between four two-pole modules/terminals, each with 250 kW.

In a preferred embodiment, all the uniform distributors are designed identically. This results in a particularly universal concept for the scalability of the test bench.

In a preferred embodiment, the test bench contains at least two energy sources. Thus, each of the energy sources can be made with a lower nominal power in order, nevertheless, to produce a higher total nominal power for the test bench.

In a preferred variant of that embodiment, at least two of the energy sources are connected to two different uniform distributors. Thus, the feeding or electrical loading of the uniform distributors by the energy sources or their connection is reduced.

In a preferred embodiment, no energy source is connected to at least one of the uniform distributors. Thus, at the uniform distributor particularly numerous third DC-voltage interfaces are available for the connection of test stations

The invention is based on the following insights, observations, and considerations, and can take the form of the preferred embodiments described below. In part for simplicity, these embodiments are also referred to as “the invention”. The embodiments can also contain parts or combinations of the above-mentioned embodiments or can correspond thereto and/or, where appropriate, they can also include embodiments not previously mentioned.

According to the invention, a DC distributor (DC: direct current), in particular a DC distributor for DC intermediate circuits with selective separation and a pre-charging device is obtained.

The invention is based on the following observations in practice:

There is a direct connection of the units in the DC intermediate circuit (bus bar). The complete intermediate circuit (bus bar) must therefore be disconnected for maintenance purposes. According to the invention, the intermediate circuit (bus bar) does not have to be disconnected. This is based on the selective activation (isolator switch) and pre-charging (pre-charging device) of the individual DC outputs (branches).

The invention relates to the following topologies: the units considered are high-dynamical, feedback-capable DC voltage sources and sinks (test station) for the testing of electrical components (tests) and for the simulation of batteries and other electrical storage means on test benches (testing modules). Typical test objects are drive and storage components such as batteries, electric drives, power converters, fuel cells, solar cells or supercapacitors.

With the topologies considered, from the output rails (bus bar/DC-voltage connection terminal) in each case a high DC power (typically 250 kW to 1 MW) is obtained at high voltages (up to 1500 V) and with large currents (up to 2000 A).

Thanks to a DC intermediate circuit bus (DC bus), a common DC intermediate circuit covering a plurality of test benches (test stations) can be realized.

The invention is based on the following insights:

Particularly in large test benches, a central DC intermediate circuit (DC bus) covering the entire test bench has various advantages.

In that way, the alternating power flows typically taking place in the test objects (charging/discharging, acceleration/recuperation) can already be compensated, whereby the network connection (first DC-voltage interface) of the test bench can be reduced substantially compared with the conventional approach.

A disadvantage of this system, however, is that for maintenance and repair purposes of a test station (also “DCU”: DC-Unit, power unit consisting of an LLC and IBC, LLC: resonance converter: power module for potential separation (transformer principle)/IBC or intermediate bus converter: step-down bridge: power module for regulating the output voltage) the complete test bench or all the DCUs (test stations), which are supplied by a UWR (“Inverter”: universal inverter/mains inverter: produces the DC intermediate circuit), have to be activated in order to be able to ensure the safety of personnel during the work.

The basic idea of the invention is therefore as follows:

Instead of a direct coupling of the DCUs (test stations) and the UWR (inverter) to one another, the DC power is passed through a modular DC-distributor (modular direct-voltage bus), which makes it possible to activate the individual DC paths (branches) selectively (isolator switch) and to guard against re-connection (safety device against re-connection).

The large startup current that typically occurs in DC networks when they are turned on again (connection of a test module to the bus bars) owing to the large intermediate circuit capacities built up, are reduced by a special pre-charging device. In this context a modular approach also comes into its own, which makes it possible to use a pre-charging device for a plurality of DC paths (branches/test modules), since it is not necessary to switch on several DCUs (test modules) at the same time.

The connection terminals (branches) can be equipped either with DC fuses (safety elements in a bridge connection) in order to connect a DCU (test station), or with a bridge (short-circuit element in a bridge connection), in order to connect an energy source.

The DC fuses of a current path are screened from nearby current paths so that a fuse can be replaced (fuse element) in an individual switched-off current path (bridge connection in a branch with an open isolator switch).

### BRIEF DESCRIPTION OF THE DRAWINGS

Further features, effects and advantages of the invention emerge form the following description of a preferred example embodiment of the invention and from the attached figures, which in each case illustrate a principle in a schematic manner:

FIG. 1: A test bench with two test stations and an energy source, shown as a schematic block circuit diagram,

FIG. 2: The test bench of FIG. 1, extended by an energy source and eight test stations with the detailed DC-voltage bus with uniform distributors,

FIG. 3: A detailed representation of part of the test bench in FIG. 2, with the central uniform distributor.

### DETAILED DESCRIPTION

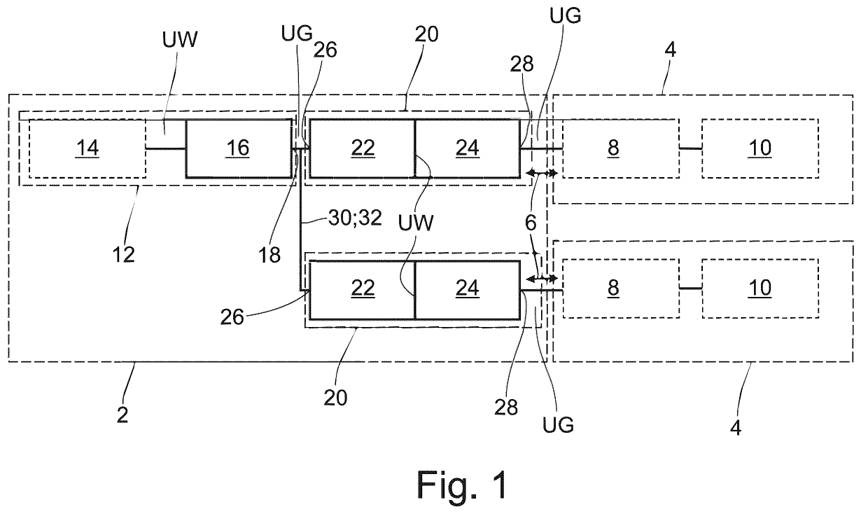

FIG. 1 shows a test bench 2 for two-pole test objects 4. In this example, in fact two test objects 4 are connected to the test bench 2. With the help of the test bench 2 an electrical test is carried out on the test objects 4. For that purpose, an electric high power 6, in this case of up to 1 MW—depending on the test—is fed into the test objects 4 or drawn from them. In the example the high power 6 is represented by a double arrow.

In the example each of the test objects 4 is in the form of a testing device 8, in this case a so-termed DC box, and the actual test object is represented in the form of a DUT 10 (Device Under Test). In this case the two DUTs 10 are, respectively, a drive battery and a drive motor of an electric vehicle. The DC box serves to connect the DUTs 10 to the test bench 2.

The test bench 2 contains an energy source 12, which in turn comprises a generator 14 and an inverter 16. In operation the generator 14 provides an alternating voltage UW, in this example a three-phase alternating voltage of 400 V. The inverter 16 is connected to the generator 14 and serves to convert the alternating voltage UW into a direct voltage UG, which is applied to a first two-pole DC-voltage interface 18 of the inverter 16 or the energy source 12.

The test bench also comprises two in each case two-pole test stations 20. Each of the test stations 20 serves for the connection of just one of the test objects 4.

Each test station 20 contains a resonance converter 22 and a step-down converter 24. The resonance converter 22 or the test station 20 comprises a second two-pole DC-voltage interface 26. On the side facing away from the resonance converter 22 the step-down converter 24 or test station 20 has a two-pole DC-voltage connection terminal 28 for the test object 4 concerned. The resonance converter 22 converts the DC voltage UG at the second DC-voltage interface 26 into an alternating voltage UW and back again into a direct voltage, which is in turn changed by the step-down converter 24 into a direct voltage UG of variable size at the DC-voltage connection terminal 28.

The test bench 2 also comprises a modular DC-voltage bus 30 with a two-pole bus bar 32. The first DC-voltage interface 18 and the second DC-voltage interface 26 are connected to the DC-voltage bus 30, as explained in greater detail later on. Accordingly, the DC-voltage bus 30 or the bus bar 32 distributes the direct voltage UG between the energy source 12 and the test stations 20.

Thus, the DC-voltage bus 30 forms a DC-voltage intermediate circuit in the test bench 2 and, when in operation, in this case carries a direct voltage UG of 825 V.

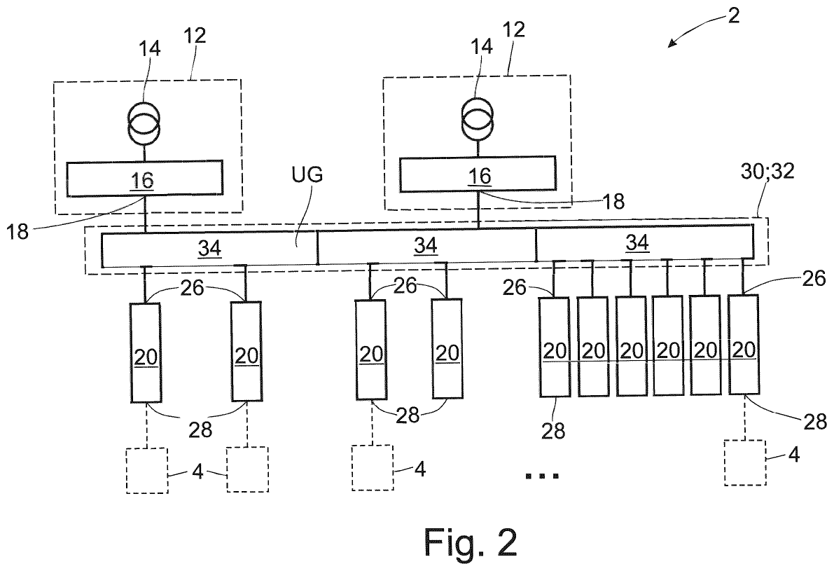

FIG. 2 shows the test bench 2 of FIG. 1 as part of an alternative test bench 2. Compared with that of FIG. 1 the alternative test bench 2 is enlarged and, besides that of FIG. 1, contains a second energy source 12 identical to the first energy source 12 and eight further test stations 20 identical to the test stations 20 of FIG. 1. All the energy sources 12 and test stations 20 are connected by way of their respective first DC-voltage interfaces 18 and second DC-voltage interfaces 26 to the DC-voltage bus 30 or bus bar 32.

However, FIG. 2 now shows in detail that, or how, the DC-voltage bus 30 is formed of a total of three uniform distributors 34 in a modular manner. The uniform distributors 34 are connected in series. Each of the uniform distributors 34 contains the, or a two-pole bus bar 32, the respective bus bars 32 being connected electrically in series so that a single two-pole bus bar 32, continuous along all three uniform distributors 34 is formed, as explained in greater detail later on.

The test bench 2 in this case also contains two energy sources 12. The two energy sources 12 are connected to different uniform distributors 34. On one of the uniform distributors 34 neither of the energy sources 12 is connected.

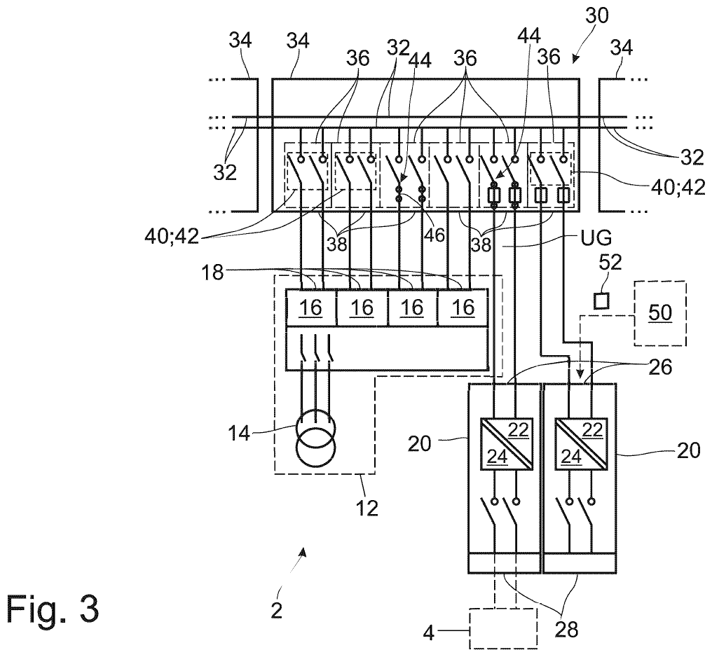

FIG. 3 shows part of the test bench 2 or DC-voltage bus 30 and thus the uniform distributor 34 in detail, taking as an example the central uniform distributor 34 from FIG. 2. In the test bench 2 all the uniform distributors 34 are designed identically, so they correspond to the one shown in detail in FIG. 3 (sometimes except for the equipment of the bridge connection 44).

FIG. 3 shows how the two-pole bus bars 32 of the individual uniform distributors 34 are connected in series in order to form the single bus bar 32 that extends through all three uniform distributors 32.

FIG. 3 also illustrates in detail the connection of the energy sources 12 and test stations 20 to the DC-voltage bus 30 and the uniform distributors 34. For that purpose, in the example the uniform distributors 34 each have six two-pole branches 36, each connected on the one hand to the bus bar 32 and on the other hand ending at the respective third DC-voltage interfaces 38. Each of the branches 36 has a two-pole isolator switch 40 in each case. This serves to connect the respective DC-voltage interface 38 to the bus bar 32 in a two-pole manner or to separate it therefrom (for the sake of clarity, only for three of the branches 36 is the isolator switch 40 indexed in the figure).

The electric connection between the energy sources 12 and test stations 20 and the DC-voltage bus 30 is made, in detail, in such manner that in each case one of the first DC-voltage interfaces 18 or second DC-voltage interfaces 26 is connected to one of the third DC-voltage interfaces 38, in each case in a two-pole manner.

FIG. 3 shows in detail that in the energy source 12 for one of the generators 14 with a nominal power of 1 MW four inverters 16 with nominal powers of 250 kW each are produced, in order to make these modular and thus better designed. Accordingly, the energy source 12 in FIG. 3 also has several, in this case four, first DC-voltage interfaces 18.

Each of the isolator switches 40 has a safety device 42 (not shown in greater detail) to guard against re-connection. Thus, in the case when one of the isolator switches 40 is open, i.e. the electric connection between the bus bar 32 and the third DC-voltage interface 38 is interrupted, a re-connection of the isolator switch 40 or a restoration of the electric connection is precluded, in order to avoid accidents etc. in the manner customary according to the state of the art.

For two of the branches 36, in FIG. 3 as an example, it is indicated that in relation to the two poles they contain one bridge connection 44 in each case. The bridge connection separates the connection between the bus bar 32 and the third DC-voltage interface 38, in this case single-poled, so that initially there is no electric connection between the two elements. In the bridge connection 44, however, optionally a short-circuit element 46 or a safety element 48 is used.

In the present case, for the four branches 36 on the left in the figure two short-circuit elements 46 are used in each case in order to re-establish the respective electrical connection between the bus bar 32 and the third DC-voltage interface 38 via the bridge connection 44. In the two branches on the right in each case two safety elements 48 are used. Thus, the branches 36 are configured in that way in order to protect the energy sources 12 by means of short-circuit elements 46 but the test stations 20 by means of safety elements 48, and thus to connect them to the bus bar 32 in an electrically safe manner according to the customary state of the art. The safety elements 48, in this case DC fuses, are screened relative to nearby current paths/poles (not shown).

The test bench 2 in this case contains a pre-charging device 50. This can optionally be connected for a certain time interval with just one of the test stations 20 and is designed for the following procedure: when with an open isolator switch 40 the test station has been connected via its second DC-voltage interface 26 to the third DC-voltage interface 38, before connection to the bus bar 32, i.e. closing of the isolator switch 40, an electrical pre-charge 52 is fed into the test station 20. For example, internal capacities in the test station 20 are charged. This prevents an undesirably large start-up current from flowing between the bus bar 32 and the test station 20 when the isolator switch 20 is subsequently closed.

### INDEXES

2 Test bench
4 Test object
6 High power
8 Testing device
10 DUT
12 Energy source
14 Generator
16 Inverter
18 First DC-voltage interface
20 Test station
22 Resonance converter
24 Step-down converter
26 Second DC-voltage interface
28 DC-voltage connection terminal
30 DC-voltage bus
32 Bus bar
34 Uniform distributor
36 Branch
38 Third DC-voltage interface
40 Isolator switch
42 Safety device (re-connection)
44 Bridge connection
46 Short-circuit element
48 Safety element
50 Pre-charging device
52 Pre-charge
UW Alternating voltage
UG Direct voltage

1. A test bench (2) for two-pole test objects (4), for the electrical testing of the test objects with the help of an electrical DC high power (UG) to be fed into and/or to be drawn from them, comprising:
at least one energy source (12), wherein each energy source (12) contains a generator (14) for an alternating voltage (UW) and an inverter (16) connected to the generator (14), which on its side facing away from the generator (14) comprises a first two-pole DC-voltage interface (18);
a plurality of two-pole test stations (20) for one of the test objects (4), wherein each test station (20) contains a resonance converter (22) with a second two-pole DC-voltage interface (26) and a step-down converter (24) connected to the resonance converter (22), which on its side facing away from the resonance converter (22) has a two-pole DC-voltage connection terminal (28) for the test object (4) concerned; and
a modular DC-voltage bus (30) which consists of a series circuit of at least two uniform distributors (34);
wherein each of the uniform distributors (34) contains a two-pole bus bar (32) configured to be connected in series and at least two two-pole branches (36) connected to the bus bar (32), which lead from the bus bar (32) to a respective third two-pole DC-voltage interface (38), wherein each of the branches (36) contains a two-pole isolator switch 940),
wherein each of the first (18) and second (6) DC-voltage interfaces is connected, respectively, to one of the third DC-voltage interfaces (38).

2. The test bench (2) according to claim 1, wherein at least one of the isolator switches (40) comprises a safety device (42) to guard against re-connection.

3. The test bench (2) according to claim 1, wherein at least one of the branches (36), in relation to at least one pole, contains a bridge connection that separates a connection between the bus bar (32) and the third DC-voltage interface (38), in which, optionally, a short-circuit element (46) of the test bench or an electric safety element (48) of the test bench can be used for bridging.

4. The test bench (2) according to, comprising a pre-charging device (50) configured to be connected to one of the test stations (20) and to feed an electric pre-charge (52) into the test station (20) connected thereto at the time.

5. The test bench (2) according to claim 1, wherein at least one of the energy sources (12) comprises a plurality of first DC-voltage interfaces (18).

6. The test bench (2) according to claim 1, wherein all the uniform distributors (34) are made identically.

7. The test bench (2) according to claim 1, wherein the test bench (2) contains at least two energy sources (12).

8. The test bench (2) according to claim 7, wherein at least two of the energy sources (12) are connected to two different uniform distributors (34).

9. The test bench (2) according to claim 1, wherein no energy source (12) is connected to at least one of the uniform distributors
